(19) United States
(12) Patent Application Publication
(10) Pub. No.: US 2009/0038550 A1
(43) Pub. Date: Feb. 12, 2009

(54) EVAPORATION SOURCE, MANUFACTURING METHOD OF THE SAME AND MANUFACTURING METHOD OF AN ORGANIC EL DISPLAY DEVICE

(75) Inventor: Tomoyuki Higo, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/182,650

(22) Filed: Jul. 30, 2008

(30) Foreign Application Priority Data
Aug. 9, 2007 (JP) 2007-207417

(51) Int. Cl. C23C 14/26; C23C 14/24; H01J 9/02

(52) U.S. Cl. 118/726; 445/24; 29/611

(57) ABSTRACT

An evaporation source includes: an insulating substrate; first electrode patterns formed in a striped manner on the substrate; second electrode patterns formed in a striped manner on the substrate so as to intersect with the first electrode patterns and be electrically insulated therefrom; and resistance layers which are disposed at intersecting portions between the first and second electrode patterns and sandwiched between the first and second electrode patterns at the intersecting portions.

### CROSS REFERENCES TO RELATED APPLICATIONS

The present invention contains subject matter related to Japanese Patent Application JP 2007-207417 filed with the Japan Patent Office on Aug. 9, 2007, the entire contents of which being incorporated herein by reference.

### BACKGROUND OF THE INVENTION

1. Field of the Invention

The present invention relates to an evaporation source, manufacturing method of the same and manufacturing method of an organic EL display device using the same.

2. Description of the Related Art

Recent years have seen attention focused on organic EL display devices using organic EL (Electro Luminescence) elements as one of thin display devices. Organic EL display devices are self-luminous and require no backlights, thus offering advantages including wide view angle and low power consumption.

An organic EL element used in an organic EL device has an organic layer made of an organic material sandwiched from top and bottom between electrodes (anode and cathode). A positive voltage is applied to the anode and a negative voltage to the cathode. This causes holes to be injected into the organic layer from the anode and electrons from the cathode. As a result, holes and electrons recombine in the organic layer to emit light.

The organic layer of the organic EL element includes a plurality of layers including hole injection layer, hole transporting layer, light-emitting layer, electron transporting layer and electron injection layer. The organic materials forming the respective functional layers have poor water resistance, making it impossible to use a wet process. Therefore, vacuum vapor deposition is used to form the organic layer. Further, in order to display a color image, three different organic materials are used for the emission colors of R (red), G (green) and B (blue) to form the RGB-emitting layers.

The aforementioned RGB-emitting layers are formed in a given color sequence on a substrate used for the formation of an organic EL element (hereinafter referred to as the “element-forming substrate”). Therefore, the element-forming substrate must be patterned so that the RGB-emitting layers are separated pixel by pixel. Vacuum vapor deposition using a vapor deposition mask is typically known as a patterning method for this purpose. It should be noted, however, that the use of a vapor deposition mask involves several problems if the mask is enlarged to respond to display devices with increasingly large screen size. Among such problems are the flexure of the vapor deposition mask and intricacy involved in its transportation.

For this reason, laser thermal transfer is known as an alternative patterning method. Laser thermal transfer consists of irradiating a laser beam onto a transfer donor and acceptor substrate attached to each other from the rear of the transfer donor, thus causing an opto-thermal conversion layer to absorb the laser beam and convert it into thermal energy. This thermal energy is used to selectively transfer part of the transfer layer (portion irradiated with the laser beam) onto the acceptor substrate.

On the other hand, Japanese Patent Laid-Open No. 2002-302759 (hereinafter referred to as Patent Document 1) discloses a technique. In this technique, electrode patterns of given shape are provided on a substrate of an evaporation source, and an evaporating material is disposed on the surface provided with the electrode patterns. Then, the evaporating material is evaporated by Joule heat resulting from the passage of a current through the electrode patterns. The evaporated material is vapor-deposited onto a target substrate which is opposed to the substrate of the evaporation source.

### SUMMARY OF THE INVENTION

However, the aforementioned laser thermal transfer requires a high-precision laser optical system because a laser is used as a heat source. As a result, the manufacturing system as a whole is highly costly, which is one of the contributors to high manufacturing cost of organic EL display devices.

An evaporation source according to an embodiment of the present invention includes an insulating substrate and first electrode patterns formed in a striped manner on the substrate. The evaporation source further includes second electrode patterns formed in a striped manner on the substrate so as to intersect with the first electrode patterns and be electrically insulated therefrom. The evaporation source still further includes resistance layers which are disposed at intersecting portions between the first and second electrode patterns and sandwiched between the first and second electrode patterns at the intersecting portions.

In the evaporation source configured as described above, given voltages are applied respectively to the first and second electrode patterns to pass a current through the resistance layers. This generates Joule heat in the resistance layers. As a result, the evaporating material can evaporate from the intersecting portions between the electrode patterns by means of the Joule heat.

The evaporation source according to the embodiment of the present invention can generate Joule heat by passing a current through the resistance layers disposed on the intersecting portions between the first and second electrode patterns, thus allowing for evaporation of the evaporating material from the intersecting portions by means of the Joule heat. As a result, with the target substrate superimposed on the substrate of the evaporation source, a vapor deposition film reflecting the layout of the intersecting portions can be formed on the target substrate by applying given voltages respectively to the first and second electrode patterns.

Further, when an organic EL display device is manufactured using the aforementioned evaporation source, an organic film reflecting the layout of the intersecting portions can be formed on an element-forming substrate by applying given voltages respectively to the first and second electrode patterns. At this time, the element-forming substrate, adapted to form an organic EL element, is superimposed on a substrate of an evaporation source. The substrate of the evaporation source has an evaporating material layer, which includes an organic sublimating material, formed thereon.

### BRIEF DESCRIPTION OF THE DRAWINGS

FIG. 1 is a sectional view illustrating a configuration example of an organic EL display device;

FIG. 2 is a sectional view illustrating an example of layered structure of organic EL elements;

FIG. 3 is a plan view illustrating the configuration of an evaporation source according to an embodiment of the present invention;

FIG. 4 is a sectional view of major sections of the evaporation source according to the embodiment of the present invention;

FIG. 5 is a sectional view of the major sections of the evaporation source according to the embodiment of the present invention;

FIG. 6 is a view illustrating the relationship between the evaporation source and electrode power sources;

FIG. 7 is an equivalent circuit diagram illustrating the connection relationship between the evaporation source and electrode power sources;

FIGS. 8A and 8B are views (1) describing a manufacturing method of the evaporation source;

FIGS. 9A and 9B are views (2) describing the manufacturing method of the evaporation source;

FIGS. 10A and 10B are views illustrating an evaporating material layer as formed on an evaporation source;

FIG. 11 is a schematic view illustrating the overall configuration of a film forming system used to manufacture an organic EL display device;

FIG. 12 is a perspective view schematically illustrating the configuration of a light-emitting layer forming section;

FIG. 13 is a view illustrating the layout relationship between the evaporation source and electrode probes;

FIG. 14 is a view describing a manufacturing method of an organic EL display device using the evaporation source according to the embodiment of the present invention;

FIGS. 15A to 15C are views illustrating the change of a voltage applied to an electrode pattern;

FIG. 16 is a plan view diagrammatically illustrating the configuration of the evaporation source with alignment marks;

FIG. 17 is a view illustrating alignment between the alignment marks;

FIGS. 18A to 18C are views illustrating the manufacturing method of an organic EL display device using the evaporation source with the alignment marks; and

FIGS. 19A to 19C are views illustrating the manufacturing method of an organic EL display device using the evaporation source with the alignment marks.

### DETAILED DESCRIPTION OF THE PREFERRED EMBODIMENT

A specific embodiment of the present invention will be described below in detail with reference to the accompanying drawings.

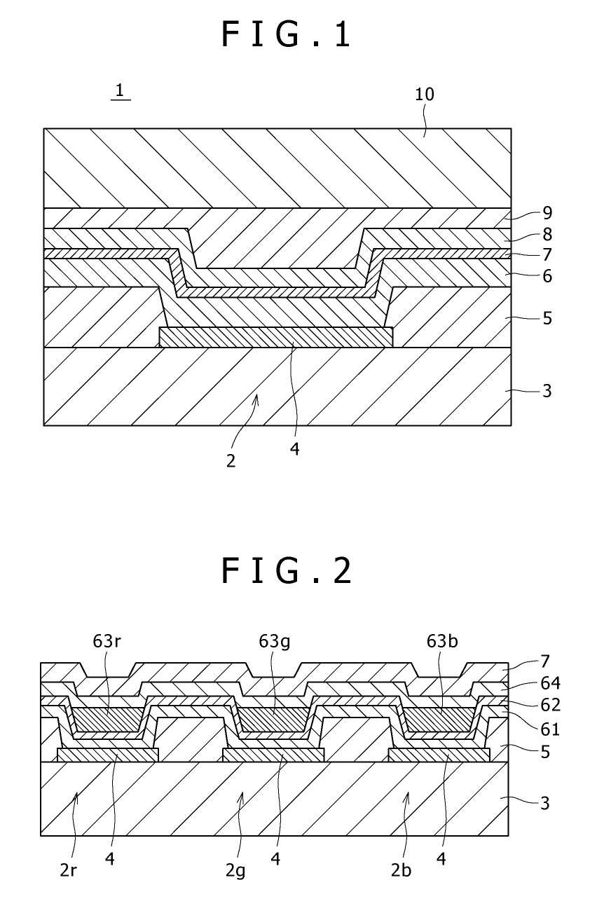

FIG. 1 is a sectional view illustrating a configuration example of an organic EL display device. An organic EL display device 1 shown in FIG. 1 includes a plurality (number) of organic EL elements 2. The organic EL elements 2 are separated by emission color, namely, R (red), G (green) and B (blue), from each other on a unit-pixel-by-unit-pixel basis.

The organic EL element 2 includes an element-forming substrate 3. On the element-forming substrate 3 are stacked an unshown switching element (e.g., thin film transistor), lower electrode 4, insulating layer 5, organic layer 6 and upper electrode 7 successively in this order. Further, the upper electrode 7 is covered with a protective layer 8, above which an opposed substrate 10 is disposed via a bonding layer 9.

The element-forming substrate 3 and opposed substrate 10 each include a transparent glass substrate. The element-forming substrate 3 and opposed substrate 10 are disposed to be opposed to each other, with the lower electrode 4, insulating layer 5, organic layer 6, upper electrode 7, protective layer 8 and bonding layer 9 sandwiched therebetween.

One of the lower electrode 4 and upper electrode 7 serves as an anode electrode, and the other as a cathode electrode. The lower electrode 4 includes a highly reflective material if the organic EL display device 1 is a top emission type. The same electrode 4 includes a transmissive material if the organic EL display device 1 is a transmissive type.

Here, we assume, as an example, that the organic EL display device 1 is a top emission type, and that the lower electrode 4 serves as an anode electrode. In this case, the lower electrode 4 includes a conductive material having a high reflectance such as silver (Ag), aluminum (Al), chromium (Cr), iron (Fe), cobalt (Co), nickel (Ni), copper (Cu), tantalum (Ta), tungsten (W), platinum (Pt) or gold (Au), or an alloy thereof.

It should be noted that if the organic EL display device 1 is a top emission type and the lower electrode 4 serves as a cathode electrode, the lower electrode 4 includes a conductive material having a small work function and high optical reflectance such as aluminum (Al), indium (In), magnesium (Mg)-silver (Ag) alloy, compound of lithium (Li) and fluorine (F), or compound of lithium and oxygen (O).

Further, if the organic EL display device 1 is a transmissive type and the lower electrode 4 serves as an anode electrode, the lower electrode 4 includes a conductive material having a high transmittance such as ITO (Indium-Tin-Oxide) or IZO (Indium-Zinc-Oxide). Still further, if the organic EL display device 1 is a transmissive type and the lower electrode 4 serves as a cathode electrode, the lower electrode 4 includes a conductive material having a small work function and high optical transmittance.

The insulating layer 5 is formed on the top surface of the element-forming substrate 3 in such a manner as to cover the surrounding portion of the lower electrode 4. The same layer 5 has a window formed for each unit pixel. The lower electrode 4 is exposed at the opening portion of the window. The same layer 5 is formed with an organic insulating material such as polyimide or photoresist, or an inorganic insulating material such as silicon oxide.

The organic layer 6 has, for example, a four-layer structure comprised of a hole injection layer 61, hole transporting layer 62, light-emitting layer 63 (63r, 63g or 63b) and electron transporting layer 64 stacked successively in this order from the side of the element-forming substrate 3, as illustrated in FIG. 2. Of these layers, the hole injection layer 61, hole transporting layer 62, and electron transporting layer 64 are common layers irrespective of the difference in RGB emission colors.

The hole injection layer 61 is formed, for example, with m-MTDATA [4,4,4-tris(3-methylphenylphenylamino)triphenylamine]. The hole transporting layer 62 is formed, for example, with α-NPD[4,4-bis(N-1-naphthyl-N-phenylamino)biphenyl]. It should be noted that the materials are not limited to the above, but other hole transporting materials may also be used such as benzidine derivative, styrylamine derivative, triphenylmethane derivative and hydrazone derivative. Further, the hole injection layer 61 and hole transporting layer 62 may each have a layered structure comprised of a plurality of layers.

The light-emitting layer 63 is formed with a different organic light-emitting material for each of the RGB color components. More specifically, a red-light-emitting layer 63r includes, for example, a mixture of ADN serving as a host material and 30 weight percent of 2,6≡bis[(4′≡methoxydiphenylamino)styryl]≡1, 5≡dicyanophthalene(BSN) serving as a dopant material. A green-light-emitting layer 63g includes, for example, a mixture of ADN serving as a host material and 5 weight percent of coumalin 6 serving as a dopant material. A blue-light-emitting layer 63b includes, for example, a mixture of ADN serving as a guest material and 2.5 weight percent of 4, 4′≡bis[2≡{4≡(N,N≡diphenylamino)phenyl}vinyl]biphenyl(DPAVBi). The respective light-emitting layers 63r, 63g and 63b are arranged in a matrix form according to the pixel color sequence.

The electron transporting layer 64 is formed, for example, with 8≡hydroxyquinolinealuminum (Alq3).

If the organic EL display device 1 is a top emission type, the upper electrode 27 includes a transparent or translucent conductive material. If the organic EL display device 1 is a transmissive type, the same electrode 27 includes a highly reflective material.

The organic EL elements 2 (red, green and blue organic EL elements 2r, 2g and 2b) each include the element-forming substrate 3, lower electrode 4, insulating layer 5, organic layer 6 and upper electrode 7 described above.

The protective layer 8 is formed, for example, to prevent moisture from reaching the upper electrode 7 and organic layer 6. Therefore, the same layer 8 is formed with a low permeable and low water-absorptive material to have a sufficient thickness. Further, if the organic EL display device 1 is a top emission type, the same layer 8 includes a material having about 80% optical transmittance because the layer must transmit the light emitted by the organic layer 6.

Still further, if the upper electrode 7 is formed with a metal thin film and if the insulating protective layer 8 is formed directly on top of the metal thin film, inorganic amorphous insulating materials such as amorphous silicon (α-SiC), amorphous silicon nitride (α-Sil-x Nx) and further amorphous carbon (α-C) can be preferably used. Such inorganic amorphous insulating materials are in grain form and have a low permeability. As a result, these materials can form the excellent organic layer 8.

The bonding layer 9 is formed, for example, with a UV (ultraviolet radiation) hardening resin. The same layer 9 is used to fasten the opposed substrate 10.

### <Configuration of the Evaporation Source>

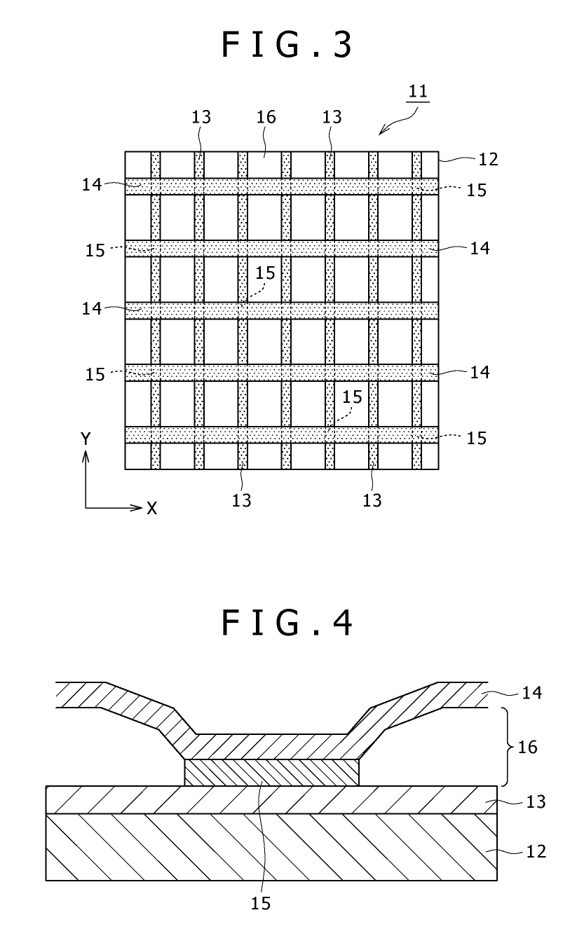

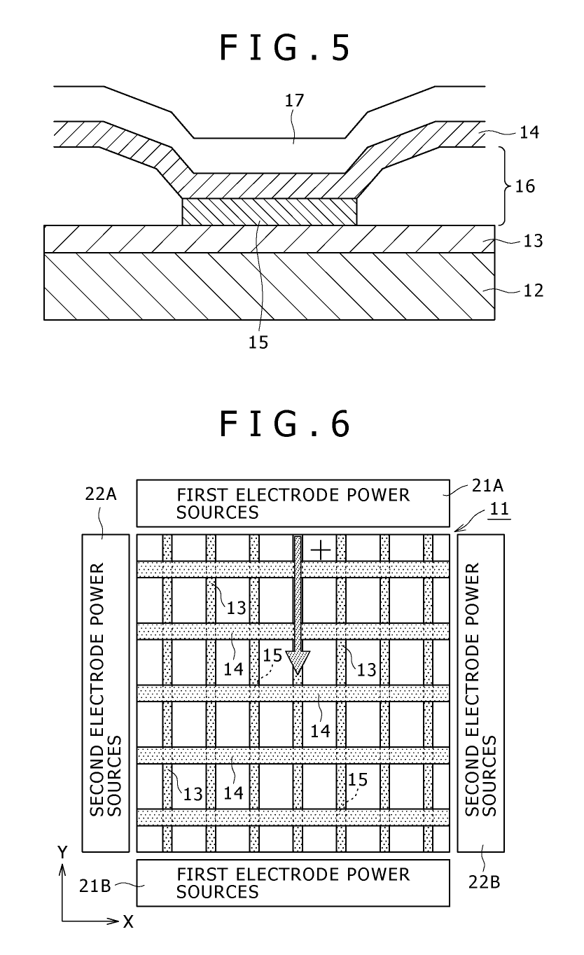

FIG. 3 is a plan view illustrating the configuration of an evaporation source used in the manufacturing process of the organic EL display device according to the embodiment of the present invention. FIG. 4 is a sectional view of major sections of the evaporation source. An evaporation source 11 includes, for example, an insulating glass substrate 12 as a base material. The glass substrate 12 has a plurality of first electrode patterns 13 formed along the Y direction in a striped manner on one of its sides. The first electrode patterns 13 are arranged in the X direction with a given spacing therebetween. The X and Y directions intersect with each other at right angle (are orthogonal to each other) across the glass substrate 12.

Further, the glass substrate 12 has a plurality of second electrode patterns 14 formed thereon such that the same patterns 14 intersect with the first electrode patterns 13. The second electrode patterns 14 are formed along the X direction in a striped manner. The second electrode patterns 14 are arranged in the Y direction with a given spacing therebetween.

A resistance heating layer 15 is provided at each of the intersecting sections between the first and second electrode patterns 13 and 14. The resistance heating layers 15 are each sandwiched between first and second electrode patterns 13 and 14 at the intersecting portion.

The first and second electrode patterns 13 and 14 both include, for example, a metal material having a low electrical resistance to avoid voltage drop resulting from the application of first and second voltages which will be described later.

In contrast, the resistance heating layers 15 include a metal material (aluminum in the present embodiment) having a higher electrical resistance than that of the materials forming the first and second electrode patterns 13 and 14 and having a high melting point. For example, the same layers 15 include a high-melting metal material such as tungsten, molybdenum or tantalum.

Except for the above intersecting portions, an insulating layer 16 mediates between the first and second electrode patterns 13 and 14. The same layer 16 provides electrical insulation between the first and second electrode patterns 13 and 14. The same layer 16 includes, for example, silicon nitride, silicon dioxide or polyimide. As for the thickness of the insulating layer 16, the film is preferably at least 200 μm thick to prevent current leaks between the first and second electrode patterns 13 and 14.

It should be noted that, as the configuration of the evaporation source 11, an unshown electrode pad portion may be omitted, and an oxidation prevention layer 17 may be formed in such a manner as to cover the second electrode pattern 14 over the glass substrate 12 so as to prevent the thermal oxidation of the second electrode pattern 14. The same layer 17 is formed, for example, with silicon nitride, silicon oxide or polyimide.

In the above example, the first electrode patterns 13 are formed underneath the second electrode patterns 14. Conversely to this, however, the second electrode patterns 14 may be formed underneath the first electrode patterns 13. Further, for the directions of the striped patterns, the first electrode patterns 13 are formed parallel to the Y direction, and the second electrode patterns 14 parallel to the X direction in the above example. Conversely to this, however, the first electrode patterns 13 may be formed parallel to the X direction, and the second electrode patterns 14 parallel to the Y direction.

The evaporation source 11 configured as described above is electrically connected to two first electrode power sources 21A and 21B and two second electrode power sources 22A and 22B, as illustrated in FIG. 6. The first electrode power sources 21A and 21B are adapted to supply a first voltage to the first electrode patterns 13. The second electrode power sources 22A and 22B are adapted to supply a second voltage to the second electrode patterns 14. In the embodiment of the present invention, for example, the second voltage is the ground potential (GND), and the first voltage is a positive voltage so that the first voltage is varied from the ground potential to a given heating voltage.

The first electrode power sources 21A and 21B are disposed one on each side along the length of the first electrode patterns 13 (in the Y direction). The second electrode power sources 22A and 22B are disposed one on each side along the length of the second electrode patterns 14 (in the X direction). The first electrode power sources 21A and 21B are both adapted to supply the first voltage to the first electrode patterns 13 via electrode pads (not shown) disposed at terminating portions along the length of the first electrode patterns 13. The second electrode power sources 22A and 22B are both adapted to supply the second voltage to the second electrode patterns 14 via electrode pads (not shown) disposed at terminating portions along the length of the second electrode patterns 14.

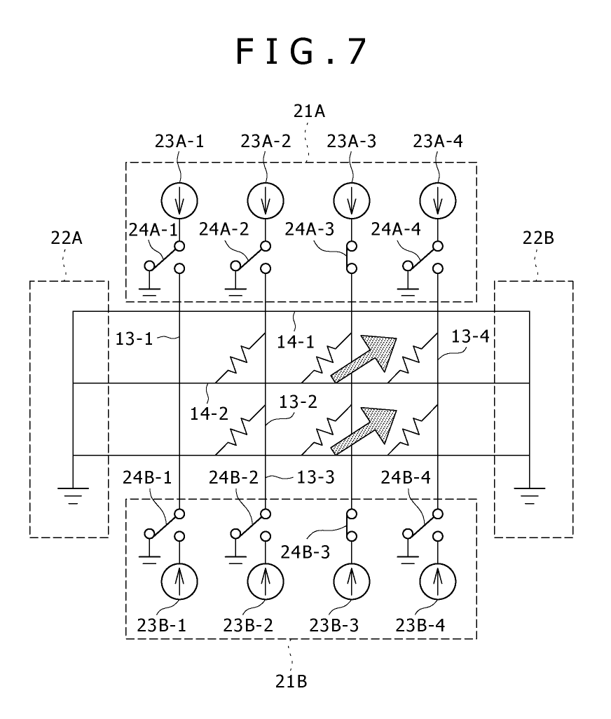

The above connection condition can be depicted by an equivalent circuit shown in FIG. 7. That is, the first electrode power source 21A includes a plurality of current sources 23A (23A-1, 23A-2, 23A-3 and 23A-4) and a plurality of switching elements 24A (24A-1, 24A-2, 24A-3 and 24A-4). The current sources 23A and switching elements 24A are associated in one-to-one fashion with the plurality of first electrode patterns 13 (13-1, 13-2, 13-3 and 13-4) (only four thereof are shown for simplification). When switched off, the switching element 24A-1 grounds the current source 23A-1 to the ground potential. When switched on, the switching element 24A-1 causes the current source 23A-1 to conduct to the first electrode pattern 13. In this regard, the other switching elements 24A-2, 24A-3 and 24A-4 also function in the same manner.

The first electrode power source 21B includes a plurality of current sources 23B (23B-1, 23B-2, 23B-3 and 23B-4) and a plurality of switching elements 24B (24B-1, 24B-2, 24B-3 and 24B-4). The current sources 23B and switching elements 24B are associated in one-to-one fashion with the plurality of first electrode patterns 13 (13-1, 13-2, 13-3 and 13-4). When switched off, the switching element 24B-1 grounds the first electrode pattern 13 to the ground potential. When switched on, the switching element 24B-1 causes the first electrode pattern 13 to conduct to the current source 23B-1. In this regard, the other switching elements 24B-2, 24B-3 and 24B-4 also function in the same manner.

On the other hand, the second electrode power sources 22A and 22B both ground all the second electrode patterns 14 to the ground potential. Therefore, if the switching element 24A-3 of the first electrode power source 21A and the switching element 24B-3 of the first electrode power source 21B are both switched on with the other switching elements all switched off as illustrated in FIG. 7, Joule heat is generated from an intersecting portion between the first and second electrode patterns 13-3 and 14-1 and that between the first and second electrode patterns 13-3 and 14-2 as a current is passed to the resistance heating layers 15 provided on the intersecting portions. Joule heat is not generated from any of the intersecting portions on the first electrode patterns 13-1, 13-2 and 13-4.

### <Manufacturing Method of the Evaporation Source>

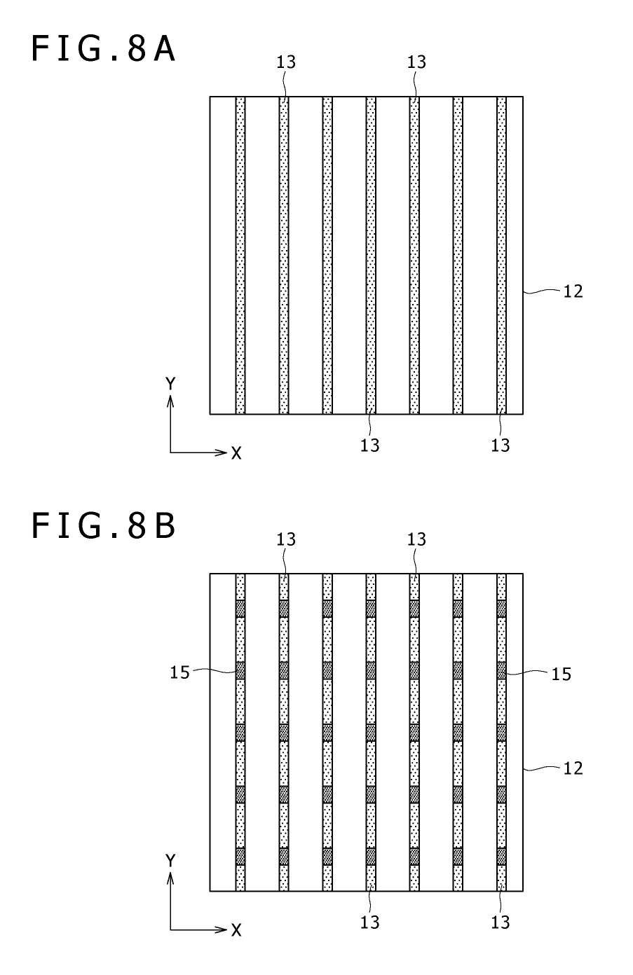

First, as illustrated in FIG. 8A, the first electrode patterns 13 are formed in a striped manner on the glass substrate 12 serving as an insulating substrate. The formation of the first electrode patterns 13 is accomplished, for example, by vapor deposition of an aluminum film over the entire surface of the glass substrate 12, followed by patterning of the aluminum film by photolithography.

Next, as illustrated in FIG. 8B, the resistance heating layers 15 are formed on the first electrode patterns 13 with a given spacing therebetween. The given spacing described here corresponds to the spacing between the second electrode patterns 14 in the Y direction. The resistance heating layers 15 are formed with a high-melting metal material such as tungsten, molybdenum or tantalum.

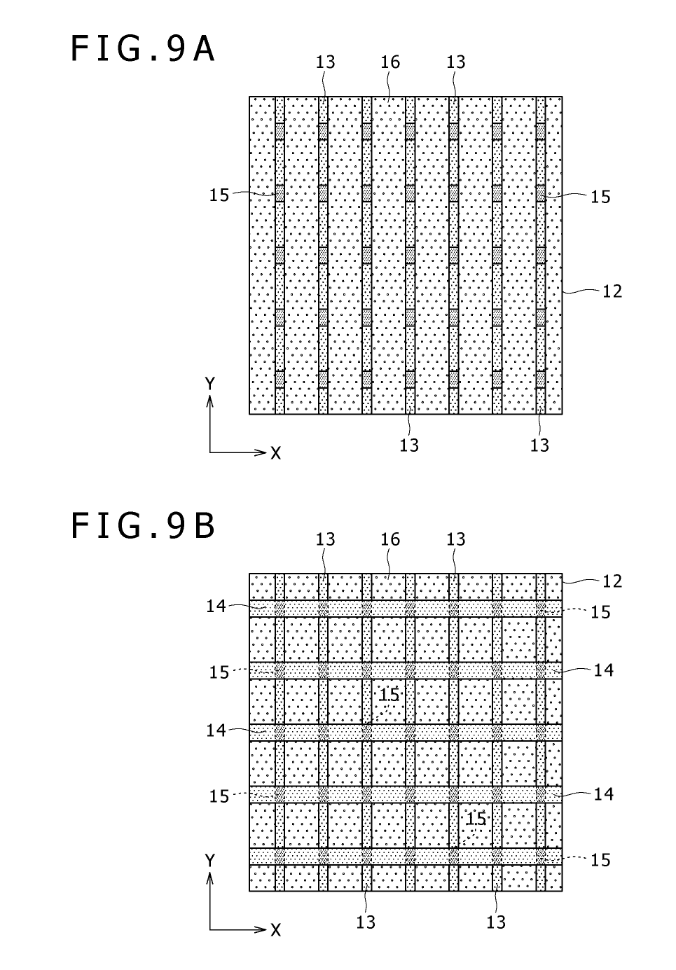

Next, as illustrated in FIG. 9A, the insulating layer 16 is formed in such a manner as to cover the pattern-formed surface of the glass substrate 12, followed by opening of the insulating layer 16 so that the resistance heating layers 15 are exposed.

Then, as illustrated in FIG. 9B, the second electrode patterns 14 are formed in a striped manner on the glass substrate 12 so that the same patterns 14 intersect with the first electrode patterns 13 at the portions where the resistance heating layers 15 are formed. The second electrode patterns 14 need only be formed by the same method as for the first electrode patterns 13.

This provides the evaporation source 11 having the resistance heating layers 15 sandwiched at the intersecting portions between the first and second electrode patterns 13 and 14. It should be noted that the oxidation prevention layer 17 need only be formed in such a manner as to cover the pattern-formed surface of the glass substrate 12 after the formation of the second electrode patterns 14.

If the organic EL display device 1 (refer to FIG. 1) is manufactured by vacuum vapor deposition using the evaporation source 11 obtained as described above, a sublimating organic material, and more specifically a sublimating organic light-emitting material, is used as an evaporating material for vacuum vapor deposition. This evaporating material is formed on the glass substrate 12 as an evaporating material layer prior to vacuum vapor deposition.

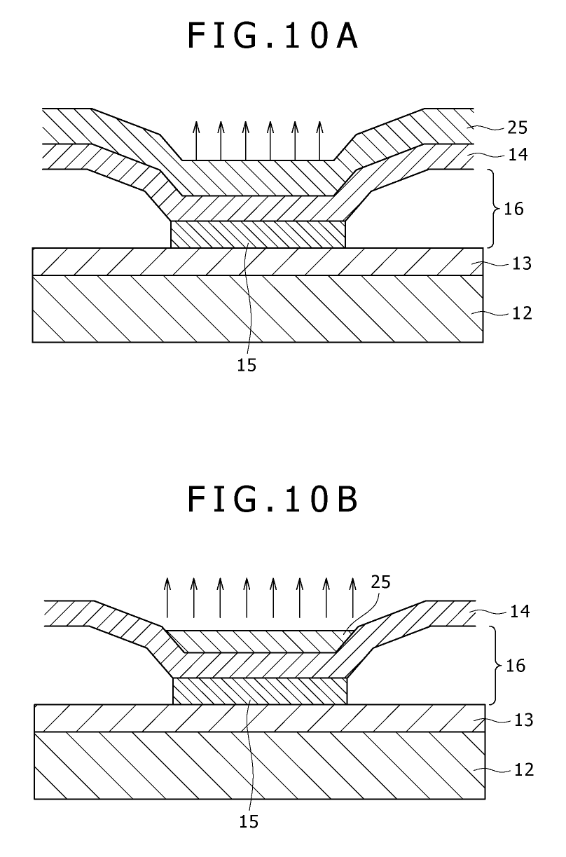

More specifically, as illustrated for example in FIG. 10A, the evaporating material is deposited by vacuum deposition on the pattern-formed surface of the glass substrate 12 or the evaporating material in ink form is coated onto the pattern-formed surface by spin coating or other technique, thus forming an evaporating material layer 25 over the glass substrate 12. Alternatively, as illustrated in FIG. 10B, the evaporating material in ink form is deposited by a printing technique such as ink jet printing onto the intersecting portions between the first and second electrode patterns 13 and 14 on the pattern-formed surface of the glass substrate 12, thus forming the evaporating material layer 25 over the glass substrate 12. If the evaporating material layer 25 is formed only at the intersecting portions between the first and second electrode patterns 13 and 14 in particular, the evaporating material can be used without any wastage, thus ensuring high efficiency in the use of the evaporating material. The thickness of the evaporating material layer 25 need only be adjusted according to the final targeted film thickness of the organic layer and other factors. If the evaporating material layer 25 is formed with a sublimating organic material (including an organic light-emitting material) as described above, the film thickness of the same layer 25 should be a maximum of about 200 nm.

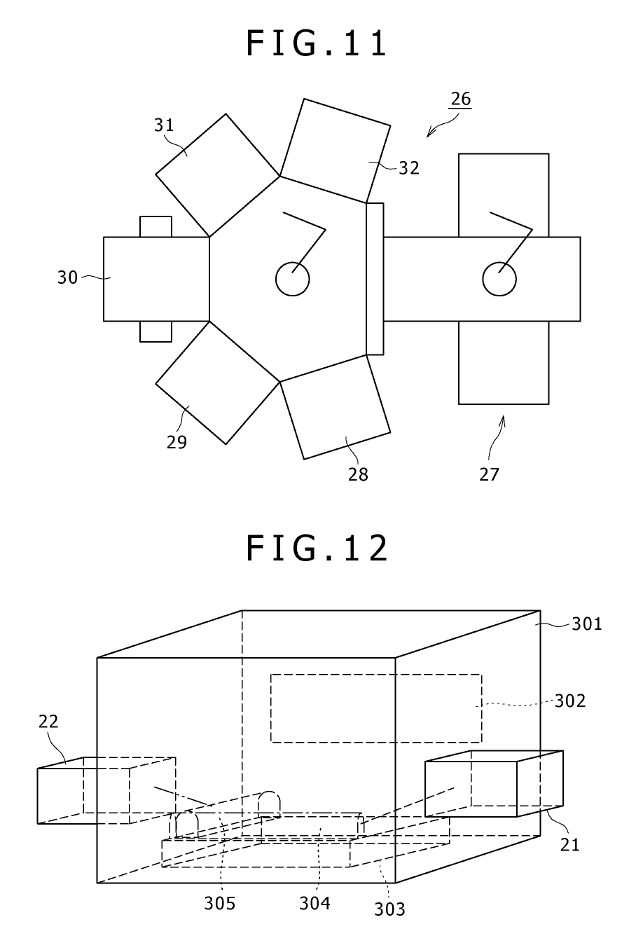

FIG. 11 is a schematic view illustrating the overall configuration of a film forming system used to form the organic layer 6 over the element-forming substrate 3 in the manufacturing process of the organic EL display device 1. A film forming system 2 illustrated in FIG. 11 includes a pre-process section 27, first common layer forming section 28, second common layer forming section 29, light-emitting layer forming section 30, third common layer forming section 31 and fourth common layer forming section 32. The pre-process section 27 handles given pre-processes required to form the organic layer 6 over the element-forming substrate 3.

The first common layer forming section 28 is adapted to form the hole injection layer 61 serving as the first common layer over the element-forming substrate 3. The second common layer forming section 29 is adapted to form the hole transporting layer 62 serving as the second common layer over the element-forming substrate 3. The light-emitting layer forming section 30 is adapted to form the light-emitting layer 63 (63r, 63g or 63b). The third common layer forming section 31 is adapted to form the electron transporting layer 64 as the third common layer over the element-forming substrate 3. The fourth common layer forming section 32 is adapted to form the electron injection layer as the fourth common layer over the element-forming substrate 3. The fourth common layer forming section 32 is not required if the organic layer 6 does not have any organic injection layer.

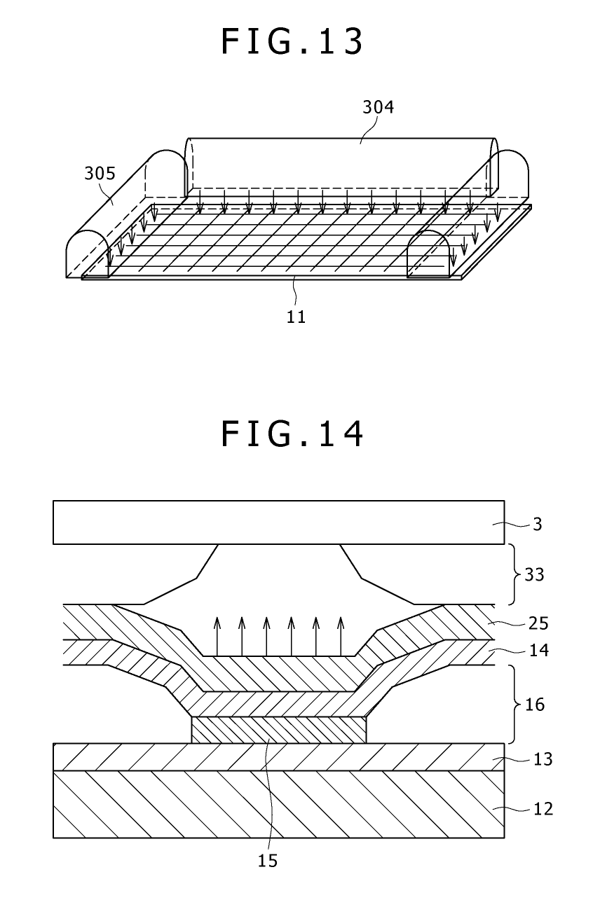

FIG. 12 is a perspective view schematically illustrating the configuration of the light-emitting layer forming section 30. A vacuum chamber 301 of the light-emitting layer forming section 30 has a transport window 302 adapted to load and unload the element-forming substrate 3. The vacuum chamber 301 includes therein a pedestal 303 adapted to support the evaporation source 11. The same chamber 301 further includes a first electrode probe 304 adapted to provide electrical connection between the evaporation source 11, supported by the pedestal 303, and the first electrode power source 21. The same chamber 301 still further includes a second electrode probe 305 adapted to provide electrical connection between the evaporation source 11 and the second electrode power source 22. FIG. 13 illustrates the layout relationship between the evaporation source 11 and electrode probes 304 and 305.

To form the light-emitting layer 63 (63r, 63g or 63b) on the element-forming substrate 3 using the film forming system 2 configured as described above, the evaporation source 11 is fitted to the pedestal 303 in the vacuum chamber 301, and the first and second electrode patterns 13 and 14 are connected respectively to the electrode probes 304 and 305.

Further, in the vacuum chamber 301, the element-forming substrate 3 is placed over the pattern-formed surface of the evaporation source 11 so that they are opposed to each other, after which a vacuum is drawn to produce a vacuum atmosphere, as illustrated in FIG. 14. At this time, a film adapted to define pixels (hereinafter referred to as the “pixel defining film”) 33 is formed in advance over the element-forming substrate 3. The pixel defining film 33 is a film having openings only at the unit pixels as described above. Before drawing a vacuum, it is preferred to have an atmosphere of inert gas such as nitrogen or argon in the vacuum chamber 301.

If, in this condition, the first voltage (heating voltage) is applied from the first electrode power source 21 to the first electrode patterns 13, and the second voltage from the second electrode power source 22 to the second electrode patterns 14, Joule heat will be generated by the principle of resistance heating of the resistance heating layers 15 as a result of the passage of a current through the same layers 15 at the intersecting portions between the first and second electrode patterns 13 and 14. At this time, the heating temperature of the evaporating material (organic material) by resistance heating is 300° C., and the heating time 5 to 10 minutes, as an example of process conditions. This causes the organic material to sublimate from the evaporating material layer 25, thus causing the sublimated organic material to be deposited onto the unit pixel portions of the element-forming substrate 3.

As a result, the light-emitting layer 63, reflecting the layout of the intersecting portions, is formed over the element-forming substrate 3. That is, if the evaporating material layer 25 is formed with an organic light-emitting material for red light emission, the red-light-emitting layer 63r reflecting the layout of the intersecting portions will be formed over the element-forming substrate 3. Further, if the evaporating material layer 25 is formed with an organic light-emitting material for green light emission, the green-light-emitting layer 63g reflecting the layout of the intersecting portions will be formed over the element-forming substrate 3. Still further, if the evaporating material layer 25 is formed with an organic light-emitting material for blue light emission, the green-light-emitting layer 63b reflecting the layout of the intersecting portions will be formed over the element-forming substrate 3. Thus, the RGB emitting layers can be coated separately over the element-forming substrate 3. It should be noted, however, that the present invention is similarly applicable to the case in which the organic layers other than the light-emitting layer (electron injection layer, electron transporting layer, hole transporting layer, hole injection layer) are coated separately by emission color using different organic materials.

Vacuum vapor deposition using the evaporation source 11 allows for separate coating of the RGB emitting layers. This makes it possible to avoid a variety of problems associated with the upsizing of the vapor deposition mask (e.g., decline in alignment accuracy caused by the flexure of the vapor deposition mask, intricacy involved in mask transportation). Further, vacuum vapor deposition using the evaporation source 11 allows for formation of the patterns of the RGB emitting layers with high accuracy over a wide area on the element-forming substrate 3 without using laser thermal transfer which leads to a high cost of the manufacturing system. As a result, organic EL display devices (large organic EL display devices in particular) can be manufactured more inexpensively than when using a laser as a heat source.

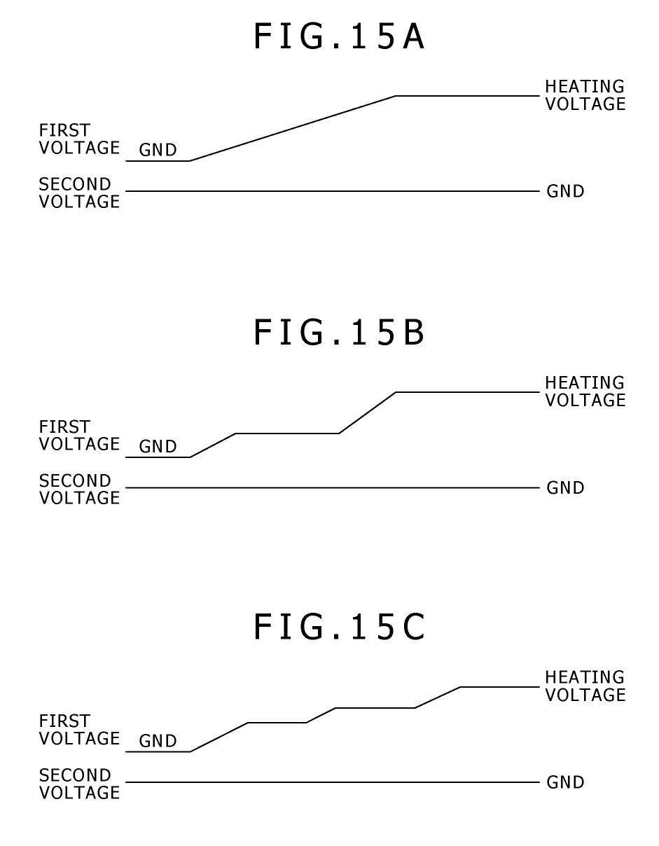

On the other hand, if the first voltage is varied with the second voltage set to the ground potential as mentioned earlier, it is preferred to raise the first voltage gradually to the given heating voltage using the first electrode power source 21. More specifically, it is preferred to raise the first voltage at a constant gradient as illustrated for example in FIG. 15A. Alternatively, it is preferred to raise the first voltage from the ground potential to the given heating voltage in a stepped manner (two or three steps) as illustrated in FIGS. 15B and 15C (or in more steps).

Further, if the switching operations (on/off operations) of the plurality of switching elements 24A and 24B are controlled by the first electrode power source 21, a current can be passed selectively to only the resistance heating layers 15 on the first electrode patterns 13 applied with the given heating voltage so as to generate Joule heat. For example, if the heating voltage is applied to the first electrode pattern 13-1 in FIG. 7, Joule heat can be generated only from the resistance heating layer 15 on the first electrode pattern 13-1. This makes it possible to cause the organic light-emitting material to evaporate only from the intersecting portion between the first and second electrode pattern 13-1 and 14-1 and that between the first and second electrode pattern 13-1 and 14-2, thus allowing for deposition of the organic light-emitting material onto the element-forming substrate 3.

By the way, the evaporation source 11 can be reused over and over by removing the used evaporating material layer 25 and forming the new evaporating material layer 25.

Incidentally, to accomplish the alignment between the evaporation source 11 and element-forming substrate 3 using alignment marks formed on the glass substrate 12 of the evaporation source 11 and a reference mark formed on the element-forming substrate (glass substrate), it is preferred to arrange the plurality of alignment marks side by side on the evaporation source 11 so as to ensure improved efficiency in the use of the organic material serving as an evaporating material.

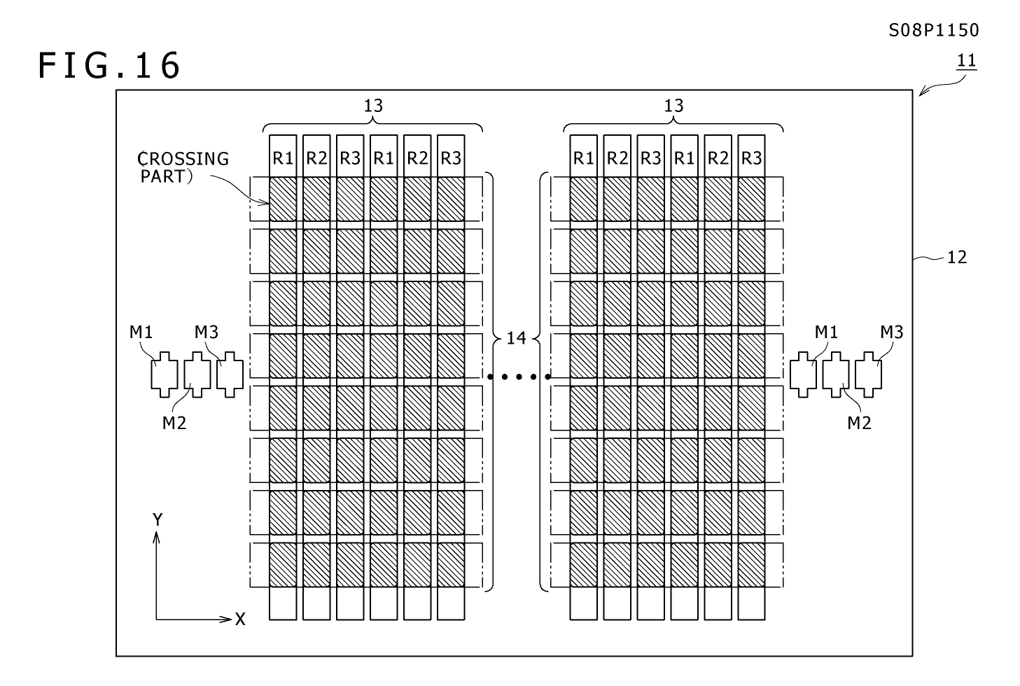

FIG. 16 is a plan view diagrammatically illustrating the configuration of the evaporation source 11 with alignment marks. In the evaporation source 11 illustrated in FIG. 16, the intersecting portions between the first and second electrode patterns 13 and 14 (portions where the resistance heating layers 15 are formed) are shown to be hatched. Further, the plurality of first electrode patterns 13 are classified (grouped) into three group columns, namely, first, second and third columns R1, R2 and R3. The first electrode patterns 13 in the first column R1 are arranged every two columns in the X direction. Similarly, the first electrode patterns 13 in the second and third columns R2 and R3 are arranged every two columns in the X direction. Thus, the first electrode patterns 13 in the respective columns are arranged repeatedly in the sequence of the first, second and third columns R1, R2 and R3 in the X direction from one side (left side in FIG. 16) to the other side (right side in FIG. 16) on the glass substrate 12 of the evaporation source 11.

The spacing between the first electrode patterns 13 in the first and second columns R1 and R2 adjacent to each other in the X direction is set to be equal to the spacing between two unit pixels adjacent to each other in the X direction (hereinafter referred to as the “pixel-to-pixel spacing”) when the element-forming substrate 3 is placed over the glass substrate 12 of the evaporation source 11 as described above. Further, the spacing between the first electrode patterns 13 in the first and third columns R1 and R3 adjacent to each other in the X direction and that between the first electrode patterns 13 in the second and third columns R2 and R3 adjacent to each other in the X direction are also set to be equal to the pixel-to-pixel spacing.

Still further, on the glass substrate 12 of the evaporation source 11, a plurality of alignment marks M1, M2 and M3 are provided side by side in the X direction so as to be associated in one-to-one fashion with the columns (R1, R2 and R3) of the first electrode patterns 13. The spacings between the alignment marks M1, M2 and M3 are set to be associated with the columns of the first electrode patterns 13. Here, the term “spacings associated with the columns of the first electrode patterns 13” refers to the spacings between the first, second and third columns R1, R2 and R3 of the first electrode patterns 13. It should be noted that, depending on the layering or directional relationship between the first and second electrode patterns 13 and 14, the spacings between the alignment marks M1, M2 and M3 may be set to be associated with the columns of the second electrode patterns 14.

The alignment marks M1, M2 and M3 are formed in the same shape (in a cross shape in the illustrated example). It should be noted that the alignment marks can be arbitrarily changed in shape. The same marks M1, M2 and M3 are provided on the glass substrate 12 each in a set of two (pair of left and right marks). The same marks M1, M2 and M3 may be provided, for example, at diagonal corner portions across the surface of the glass substrate 12.

On one side of the glass substrate 12 (left side in FIG. 16) are provided the three alignment marks M1, M2 and M3 side by side in the X direction. Also on the other side of the first electrode patterns 13 (right side in FIG. 16) are provided the three alignment marks M1, M2 and M3 side by side in the X direction. Of these, the pair of left and right first alignment marks M1 are provided to be associated with the first electrode patterns 13 in the first column R1. Further, the pair of left and right first alignment marks M2 are provided to be associated with the first electrode patterns 13 in the second column R2. Still further, the pair of left and right first alignment marks M3 are provided to be associated with the first electrode patterns 13 in the third column R3.

The above alignment marks M1, M2 and M3 are arranged side by side with the same spacings as those between the first electrode patterns 13 in the first, second and third columns R1, R2 and R3 in the X direction (direction of the columns of the first electrode patterns 13). The spacing between the alignment marks M1 and M2 adjacent to each other in the X direction is set to be equal to the pixel-to-pixel spacing. The spacing between the alignment marks M2 and M3 adjacent to each other in the X direction is also set to be equal to the pixel-to-pixel spacing. Further, the positional relationship between the first electrode patterns 13 in the first column R1 and the left and right alignment marks M1, that between the first electrode patterns 13 in the second column R2 and the left and right alignment marks M2, and that between the first electrode patterns 13 in the third column R3 and the left and right alignment marks M3, are set to be the same. Here, the first electrode patterns 13 in the first, second and third columns R1, R2 and R3 are all arranged with the same spacings. However, even if the spacing between the first electrode patterns 13 in the first and second column R1 and R2 is set to be different from that between the first electrode patterns 13 in the second and third column R2 and R3, there is no problem so long as the positional relationship is the same between the alignment marks and the first electrode patterns 13 in the respective columns.

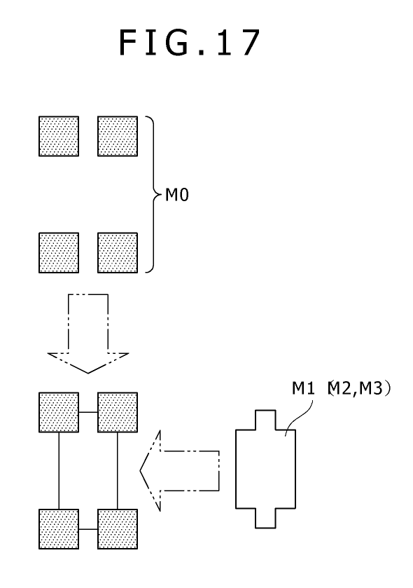

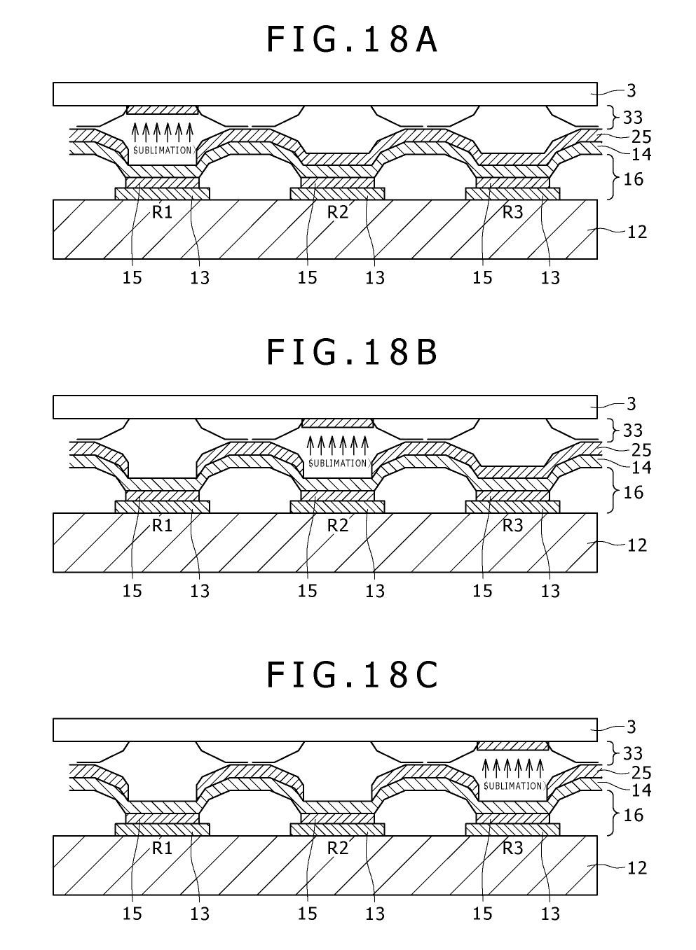

To form the light-emitting layer 63 on the element-forming substrate 3 using the evaporation source 11 having the alignment marks configured as described above, the reference mark formed on the element-forming substrate 3 is aligned with one of the alignment marks M1, M2 and M3 when the element-forming substrate 3 is placed over the evaporation source 11. For example, if a reference mark M0 is formed on the element-forming substrate 3 in the shape as shown in FIG. 17, the reference mark M0 on the element-forming substrate 3 is aligned with the alignment mark M1 on the evaporation source 11 as a first vacuum deposition process step. The alignment between the reference mark M0 and alignment mark M1 is accomplished by image processing technique using, for example, an imaging camera. With the two marks aligned with each other, the heating voltage is applied only to the first electrode patterns 13 in the first column R1, and not to the same patterns 13 in the second and third columns R2 and R3. This generates Joule heat from the resistance heating layers 15 on the first electrode patterns 13 in the first column R1, thus causing the organic light-emitting material to sublimate from the evaporating material layer 25 by the Joule heat as illustrated in FIG. 18A. As a result, on the element-forming substrate 3 having the pixel defining film 33 formed thereon, the organic light-emitting material is deposited only onto the unit pixel portions which are opposed to the intersecting portions between the first electrode patterns 13 in the first column R1 and second electrode patterns 14.

Next, as a second vacuum deposition process step, the element-forming substrate 3 different from that used in the first vacuum deposition process step is placed over the same evaporation source 11 as used in the first vacuum deposition process step. In this case, the reference mark formed on the element-forming substrate 3 is aligned with the alignment mark M2. Then, with the two marks aligned with each other, the heating voltage is applied only to the first electrode patterns 13 in the second column R2, and not to the same patterns 13 in the first and third columns R1 and R3. This generates Joule heat from the resistance heating layers 15 on the first electrode patterns 13 in the second column R2, thus causing the organic light-emitting material to sublimate from the evaporating material layer 25 by the Joule heat as illustrated in FIG. 18B. As a result, on the element-forming substrate 3 having the pixel defining film 33 formed thereon, the organic light-emitting material is deposited only onto the unit pixel portions which are opposed to the intersecting portions between the first electrode patterns 13 in the second column R2 and second electrode patterns 14.

Next, as a third vacuum deposition process step, the element-forming substrate 3 different from that used in the first or second vacuum deposition process step is placed over the same evaporation source 11 as used in the first and second vacuum deposition process steps. In this case, the reference mark formed on the element-forming substrate 3 is aligned with the alignment mark M3. Then, with the two marks aligned with each other, the heating voltage is applied only to the first electrode patterns 13 in the third column R3, and not to the same patterns 13 in the first and second columns R1 and R2. This generates Joule heat from the resistance heating layers 15 on the first electrode patterns 13 in the third column R3, thus causing the organic light-emitting material to sublimate from the evaporating material layer 25 by the Joule heat as illustrated in FIG. 18C. As a result, on the element-forming substrate 3 having the pixel defining film 33 formed thereon, the organic light-emitting material is deposited only onto the unit pixel portions which are opposed to the intersecting portions between the first electrode patterns 13 in the third column R3 and second electrode patterns 14.

The aforementioned process steps allow for formation of the light-emitting layer 63 on the three element-forming substrates 3 using the evaporation source 11 having the evaporating material layer 25 formed thereon. For example, when the evaporating material layer 25 is formed with an organic light-emitting material for red light emission, the red-light-emitting layer 63r can be formed on the three element-forming substrates 3 using the evaporation source 11 having the same evaporating material layer 25 formed thereon three times. When the evaporating material layer 25 is formed with an organic light-emitting material for green light emission, the green-light-emitting layer 63g can be formed on the three element-forming substrates 3 using the evaporation source 11 having the same evaporating material layer 25 formed thereon. When the evaporating material layer 25 is formed with an organic light-emitting material for blue light emission, the blue-light-emitting layer 63b can be formed on the three element-forming substrates 3 using the evaporation source 11 having the same evaporating material layer 25 formed thereon. As a result, if the evaporating material layer 25 is formed uniformly with an organic light-emitting material over the glass substrate 12 of the evaporation source 11, the efficiency in the use of the organic light-emitting material (evaporating material) can be improved as compared to the case in which the evaporation source 11 having the evaporating material layer 25 formed thereon is used only once.

In the above example of process steps, the case has been described in which the evaporation source 11 having the same evaporating material layer 25 formed thereon is used three times to form the light-emitting layer 63. Alternatively, however, the light-emitting layer 63 can be formed to a desired thickness on the single (same) element-forming substrate 3 by using the evaporation source 11 having the same evaporating material layer 25 formed thereon a plurality of times.

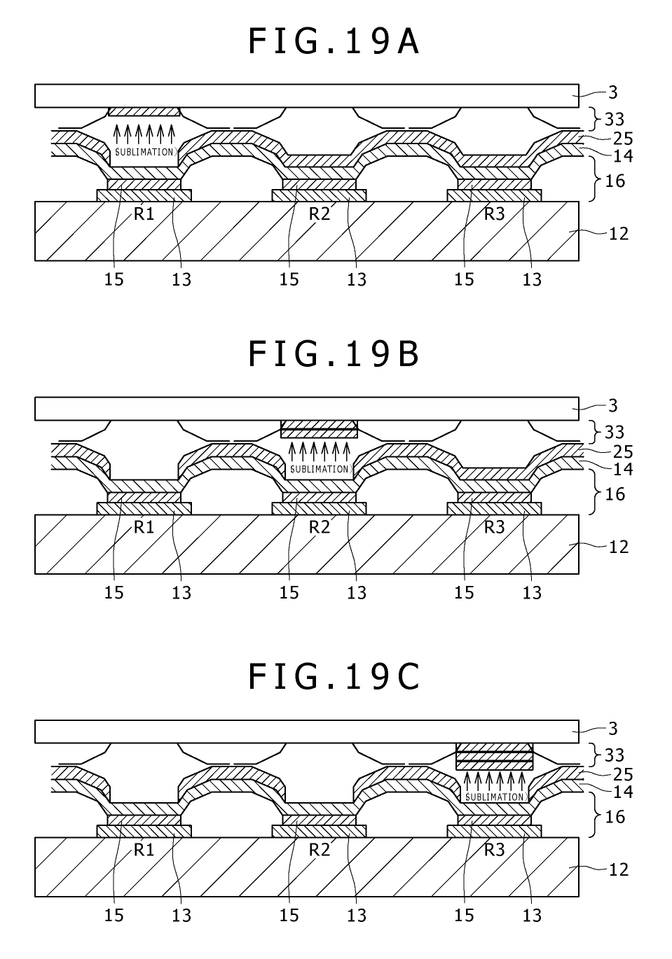

The specific process steps are as follows. That is, as a first vacuum deposition process step, the reference mark M0 formed on the element-forming substrate 3 is aligned with the alignment mark M1 on the evaporation source 11 having the evaporating material layer 25 formed thereon. Then, with the two marks aligned with each other, the heating voltage is applied only to the first electrode patterns 13 in the first column R1, and not to the same patterns 13 in the second and third columns R2 and R3. This generates Joule heat from the resistance heating layers 15 on the first electrode patterns 13 in the first column R1, thus causing the organic light-emitting material to sublimate from the evaporating material layer 25 by the Joule heat as illustrated in FIG. 19A. As a result, on the element-forming substrate 3 having the pixel defining film 33 formed thereon, the organic light-emitting material is deposited only onto the unit pixel portions which are opposed to the intersecting portions between the first electrode patterns 13 in the first column R1 and second electrode patterns 14.

Next, as a second vacuum deposition process step, the same element-forming substrate 3 as used in the first vacuum deposition process step is placed over the same evaporation source 11 as used in the first vacuum deposition process step. In this case, the reference mark M0 formed on the element-forming substrate 3 is aligned with the alignment mark M2. Then, with the two marks aligned with each other, the heating voltage is applied only to the first electrode patterns 13 in the second column R2, and not to the same patterns 13 in the first and third columns R1 and R3. This generates Joule heat from the resistance heating layers 15 on the first electrode patterns 13 in the second column R2, thus causing the organic light-emitting material to sublimate from the evaporating material layer 25 by the Joule heat as illustrated in FIG. 19B. As a result, on the element-forming substrate 3 having the pixel defining film 33 formed thereon, the organic light-emitting material is deposited only onto the unit pixel portions which are opposed to the intersecting portions between the first electrode patterns 13 in the second column R2 and second electrode patterns 14.

Next, as a third vacuum deposition process step, the same element-forming substrate 3 as used in the first and second vacuum deposition process steps is placed over the same evaporation source 11 as used in the first and second vacuum deposition process steps. In this case, the reference mark M0 formed on the element-forming substrate 3 is aligned with the alignment mark M3. Then, with the two marks aligned with each other, the heating voltage is applied only to the first electrode patterns 13 in the third column R3, and not to the same patterns 13 in the first and second columns R1 and R2. This generates Joule heat from the resistance heating layers 15 on the first electrode patterns 13 in the third column R2, thus causing the organic light-emitting material to sublimate from the evaporating material layer 25 by the Joule heat as illustrated in FIG. 19C. As a result, on the element-forming substrate 3 having the pixel defining film 33 formed thereon, the organic light-emitting material is deposited only onto the unit pixel portions which are opposed to the intersecting portions between the first electrode patterns 13 in the third column R3 and second electrode patterns 14.

As a result of the aforementioned three vacuum deposition process steps, the organic light-emitting material is deposited three times onto the same unit pixel portion on the element-forming substrate 3. This makes it possible to form the light-emitting layer 63 thicker than the vacuum-deposited film formed by a single vacuum deposition process step. Further, the larger number of vacuum deposition process steps, the thicker the light-emitting layer 63 becomes at the unit pixel portion on the element-forming substrate 3. This makes it possible to adjust the film thickness of the light-emitting layer 63 by using, as a parameter, the number of vacuum deposition process steps. Incidentally, if the organic EL display device 1 is a top emission type, the electron transporting layer or hole transporting layer may be adjusted in thickness for each of the RGB emission colors. The present invention is also applicable to such a case in a flexibly manner.

It should be understood by those skilled in the art that various modifications, combinations, sub-combinations and alterations may occur depending on design requirements and other factors insofar as they are within the scope of the appended claims or the equivalents thereof.

What is claimed is:

1. An evaporation source comprising:
an insulating substrate;
first electrode patterns formed in a striped manner on the substrate;
second electrode patterns formed in a striped manner on the substrate so as to intersect with the first electrode patterns and be electrically insulated therefrom; and
resistance layers which are disposed at intersecting portions between the first and second electrode patterns and sandwiched between the first and second electrode patterns at the intersecting portions.

2. The evaporation source of claim 1, wherein
a plurality of alignment marks are provided side by side with a spacing therebetween on the substrate, the spacing being associated with the spacing between columns of the first or second electrode patterns.

3. A manufacturing method of an evaporation source comprising the steps of:
forming first electrode patterns in a striped manner on an insulating substrate;
forming resistance layers on the first electrode patterns with a given spacing therebetween; and
forming second electrode patterns in a striped manner so that the second electrode patterns intersect with the first electrode patterns at portions where the resistance heating layers are formed.

4. A manufacturing method of an organic electroluminescence display device using an evaporation source,
the evaporation source including
an insulating substrate;
first electrode patterns formed in a striped manner on the substrate;
second electrode patterns formed in a striped manner on the substrate so as to intersect with the first electrode patterns and be electrically insulated therefrom; and
resistance layers which are disposed at intersecting portions between the first and second electrode patterns and sandwiched between the first and second electrode patterns at the intersecting portions,
the manufacturing method of an organic electroluminescence display device comprising the steps of:
superimposing an element-forming substrate, adapted to form an organic electroluminescence element, on a substrate of the evaporation source having an evaporating material layer formed thereon, the evaporating material layer including an organic sublimating material; and
causing an organic material to sublimate by heat generated in the resistance layers disposed at the intersecting portions by applying a first and second voltages respectively to the first and second electrode patterns so as to form an organic film on the element-forming substrate.

5. The manufacturing method of an organic electroluminescence display device of claim 4, comprising the step of
raising the first voltage gradually to a given heating voltage with the second voltage set to the ground potential.

6. A manufacturing method of an organic electroluminescence display device using an evaporation source,
the evaporation source including
an insulating substrate;
first electrode patterns formed in a striped manner on the substrate;
second electrode patterns formed in a striped manner on the substrate so as to intersect with the first electrode patterns and be electrically insulated therefrom; and
resistance layers which are disposed at intersecting portions between the first and second electrode patterns and sandwiched between the first and second electrode patterns at the intersecting portions,
wherein a plurality of alignment marks are provided side by side with a spacing therebetween on the substrate, the spacing being associated with the spacing between columns of the first or second electrode patterns,
the manufacturing method of an organic electroluminescence display device comprising the steps of:
superimposing an element-forming substrate, adapted to form an organic electroluminescence element, on a substrate of the evaporation source each time a vacuum deposition process is performed while switching an alignment mark among the plurality of alignment marks, the alignment mark to be aligned with a reference mark formed on the element-forming substrate; and
causing an organic material to sublimate by heat generated in the resistance layers disposed at the intersecting portions by applying a first and second voltages respectively to the first and second electrode patterns so as to form an organic film on the element-forming substrate.

7. The manufacturing method of an organic electroluminescence display device of claim 6, comprising the step of
superimposing a different element-forming substrate on the substrate of the evaporation source each time the vacuum deposition process is performed.

8. The manufacturing method of an organic electroluminescence display device of claim 6, comprising the step of
superimposing the same element-forming substrate on the substrate of the evaporation source each time the vacuum deposition process step is performed.
